(19) United States
(12) Patent Application Publication
(10) Pub. No.: US 2026/0075963 A1
(43) Pub. Date: Mar. 12, 2026

(54) TRIGGERABLE ENCAPSULANT MATERIAL FOR PHOTOVOLTAICS, PHOTOVOLTAIC MODULE, AND METHOD OF PRODUCING TRIGGERABLE ENCAPSULANT MATERIAL

(71) Applicant: BRASKEM AMERICA, INC., Philadelphia, PA (US)

(72) Inventors: Sarah MITCHELL, Pittsburgh, PA (US); Kimberly Miller MCLOUGHLIN, Pittsburgh, PA (US); Hadi Mohammadi, Pittsburgh, PA (US); Nei Swbastiao Dominques, JR., Pittsburgh, PA (US); Yu-kai Su, Pittsburgh, PA (US)

(21) Appl. No.: 19/320,694

(22) Filed: Sep. 5, 2025

Related U.S. Application Data
(60) Provisional application No. 63/691,477, filed on Sep. 6, 2024.

(51) Int. Cl. H10F 19/80; C08F 8/34; C08J 5/18

(52) U.S. Cl. CPC H10F 19/804; C08F 8/34; C08J 5/18; C08F 2810/20; C08J 2323/08

(57) ABSTRACT

The invention relates to a triggerable encapsulant material for photovoltaics, comprising a reversibly-crosslinked polymer network formed from the reaction product of: (i) a crosslinker composition comprising a crosslinker molecule having a —Sₙ— moiety and at least two polymerizable groups, wherein n is an integer of from 2 to 8, and (ii) a monomer, polymer, or combination thereof, comprising at least one C═C double bond or otherwise being capable of undergoing a free radical reaction or polymerization, in the presence of (iii) a free radical generator.

### CROSS-REFERENCE TO RELATED APPLICATIONS

This application claims the benefit of priority under 35 U.S.C. § 119(e) to U.S. Provisional Patent Application No. 63/691,477, filed on Sep. 6, 2024, which is herein incorporated by reference in its entirety.

### FIELD OF THE INVENTION

This invention generally relates to the field of triggerable encapsulant materials for photovoltaics comprising reversibly-crosslinked polymers having reprocessing/recycling capabilities.

### BACKGROUND OF THE INVENTION

Solar energy is a rapidly growing market of renewable energy due to the increasing demand for sustainable sources of energy. The cost to acquire solar energy has decreased in the past years, making it an approachable renewable form of energy for consumers.

One key aspect of solar energy is the long-term performance of solar panels. In this regard, encapsulant materials play a critical role in the longevity of a solar panel, protecting the photovoltaic (PV) cell from environmental stressors and improving cell stability. Key properties of these materials include chemical inertness, high oxygen barrier, optical properties, and thermal stability, among others.

The most common encapsulant material is ethylene-vinyl acetate copolymers (EVA), while other materials include polyolefin elastomers (POE), polyvinyl butyral (PVB), and thermoplastic polyolefins (TPO). Through a lamination process, these materials seal together a PV module, via a curing step where the encapsulant material becomes crosslinked. While this crosslinked encapsulant provides the stability necessary for a PV module to achieve a long life, it makes dissembling and recycling a PV module difficult.

Current recycling technologies for PV modules include grinding a PV module and burning off the crosslinked encapsulant material. This process makes it difficult to recover the valuable components of a PV cell, which is an important drawback.

There thus remains a continuous need in the art for developing novel triggerable materials, which maintain the properties of traditional PV encapsulant materials, while also providing greater ease with respect to recyclability.

### SUMMARY OF THE INVENTION

In one aspect, provided herein is a triggerable encapsulant material for photovoltaics, comprising a reversibly-crosslinked polymer network formed from the reaction product of: (i) a crosslinker composition comprising a crosslinker molecule having a —Sₙ— moiety and at least two polymerizable groups, wherein n is an integer of from 2 to 8, and (ii) a monomer, polymer, or combination thereof, comprising at least one C═C double bond or otherwise being capable of undergoing a free radical reaction or polymerization, in the presence of (iii) a free radical generator, wherein the reversibly-crosslinked polymer network contains polymer chains crosslinked via —S—S— bonds, which dissociate at a temperature of greater than 50° C. (e.g., greater than 100° C.).

In another aspect, provided herein is a method of producing a triggerable encapsulant material, comprising reacting, by free radical reaction or polymerization, (i) a crosslinker composition comprising a crosslinker molecule having a —Sₙ— moiety and at least two polymerizable groups, wherein n is an integer of from 2 to 8, and (ii) a monomer, polymer, or combination thereof, comprising at least one C═C double bond or otherwise being capable of undergoing a free radical reaction or polymerization, in the presence of (iii) a free radical generator, to produce a triggerable encapsulant material comprising a reversibly-crosslinked polymer network containing polymer chains crosslinked via —S—S— bonds, which dissociate at a temperature of greater than 50° C. (e.g., greater than 100° C.)

Another aspect of the invention relates to a photovoltaic module comprising one or more layers of a film formed from the triggerable encapsulant material as described from the above aspect of the invention.

Additional aspects, advantages and features of the invention are set forth in this specification, and in part will become apparent to those skilled in the art on examination of the following, or may be learned by practice of the invention. The inventions disclosed in this application are not limited to any particular set of or combination of aspects, advantages and features. It is contemplated that various combinations of the stated aspects, advantages and features make up the inventions disclosed in this application.

### BRIEF DESCRIPTION OF THE DRAWINGS

FIG. 1 is a schematic illustration of a method of producing a triggerable encapsulant material according to an embodiment of the present invention.

FIG. 2 is a schematic illustration of a method of producing a triggerable encapsulant material according to another embodiment of the present invention.

FIG. 3 is a schematic illustration of PV modules with triggerable encapsulant materials.

### DETAILED DESCRIPTION OF THE INVENTION

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and may be practiced with any other embodiment(s).

As used herein, “about” will be understood by persons of ordinary skill in the art and will vary to some extent depending upon the context in which it is used. If there are uses of the term which are not clear to persons of ordinary skill in the art, given the context in which it is used, “about” will mean up to plus or minus 10% of the particular term.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein may be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

The disclosure provides a triggerable encapsulant material for photovoltaics and method for making the same, employing a reversibly-crosslinked polymer network formed from the reaction product of a crosslinker composition comprising a crosslinker molecule having a —Sₙ— moiety and at least two polymerizable groups, a monomer (in-reactor process), a polymer (post-reactor process), or combination thereof, and a free radical generator.

In one aspect, the present invention relates to a triggerable encapsulant material, where the reversibly-crosslinked polymer network contains polymer chains crosslinked via —S—S— bonds (dynamic covalent chemistry), for example, disulfides. Disulfides upon heating dissociate to break the disulfide bond and form two thioradicals, upon cooling the disulfide bond reforms.

The present invention incorporates a disulfide bond into a polymer network via a dynamic crosslinker to form a triggerable encapsulant material, which is dynamically crosslinked, so that when it is heated (T>100° C.), it can be reprocessed and recovered. These triggerable materials maintain the properties of traditional PV encapsulant materials, while also providing recyclability.

### Triggerable Encapsulant Material

One aspect of the invention relates to a triggerable encapsulant material for photovoltaics, comprising a reversibly-crosslinked polymer network formed from the reaction product of (i) a crosslinker composition comprising a crosslinker molecule having a —Sₙ— moiety and at least two polymerizable groups, wherein n is an integer of from 2 to 8, and (ii) a monomer, polymer, or combination thereof, comprising at least one C═C double bond or otherwise being capable of undergoing a free radical reaction or polymerization, in the presence of (iii) a free radical generator, wherein the reversibly-crosslinked polymer network contains polymer chains crosslinked via —S—S— bonds, which dissociate at a temperature of greater than 50° C. (e.g., greater than 100° C.).

The crosslinker composition comprises a dynamic crosslinker, meaning that the polymer chains of the polymers, formed from polymerization of the crosslinker molecules and the monomers, polymers or combinations thereof, are covalently linked via a reversible linkage provided by the crosslinker that dissociates at an elevated temperature and reassociates upon cooling. The crosslinker also contains at least two polymerizable groups allowing for its incorporation into a polymer network via polymerization.

The crosslinker composition comprises a crosslinker molecule having a —Sₙ— moiety (n is an integer of from 2 to 8, e.g., 2 or 3) and has at least two polymerizable groups. The dynamic nature comes from the disulfide or polysulfide bond that dissociates to form a stable thiyl radical upon heating and reassociates back to reform the disulfide or polysulfide bond upon cooling down to room temperature. The polymerizable groups may comprise an unsaturated bond capable of polymerization reaction to allow for incorporation of the crosslinker into a polymer network during polymerization reaction. For instance, the polymerizable group can comprise a C═C double bond. The two polymerizable groups may be the same or different.

The unsaturated bond (e.g., C═C double bond) capable of undergoing a polymerization reaction is in a functional group including but not limited to at least one among an alkene, an alkyne, a nitrile, a vinyl group, an acyl, an acrylate, a (meth)acrylate, an acrylamine, a (meth)acrylamine, a styrene, a vinyl pyridine, or combinations thereof.

In some embodiments, the crosslinker molecule may be represented by Formula (I), (II), (III), (IV), (V) or (VI):

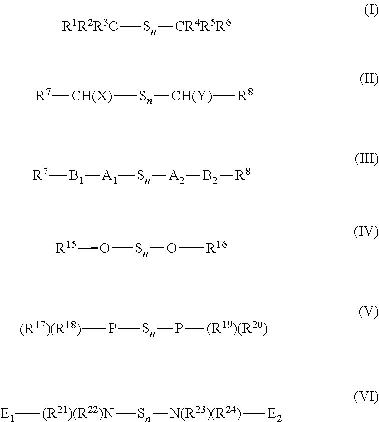

Integer n is from 2 to 8, such as 2 or 5, 2 to 4, or 2 to 3. Typically, n is 2 or 3. In one embodiment, n is 2. In one embodiment, n is 3.

Each of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, and R²⁴ is independently a hydrogen atom, a halogen atom, a C₁₋₂₀ linear or branched alkyl, a C₂₋₂₀ alkenyl, a C₂₋₂₀ alkynyl, a nitrile, a hydroxyl, an ester having from 1 to 20 carbon atoms, an ether having from 1 to 20 carbon atoms, a thioether having from 1 to 20 carbon atoms, a ketone having from 1 to 20 carbon atoms, an imine, an amide, a primary amine, a secondary amine, a tertiary amine, a trifluoromethyl, a phenyl, a benzyl, a phenol, a pentafluorophenyl, a nitroxyl, or a silicone having from 1 to 20 carbon atoms. Each of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, and R²⁴ may be optionally substituted by one or more alkyl, alkenyl, hydroxyl, or halide groups. The optional substituents replace the hydrogen atom(s) of these R variables. Exemplary substituents are C₁-C₆ alkyl (linear or branched), C₂-C₆ alkenyl, hydroxyl, or halide groups.

X represents CHR⁹R¹⁰, OH, SH, or NHR¹¹. Y represents CHR¹²R¹³, OH, SH, or NHR¹⁴.

Each of A₁ and A₂ is independently absent, a C₁-C₂₀ alkylene, a C₃-C₂₀ cycloalkylene, a divalent form of C₂-C₂₀ alkene, a divalent form of C₂-C₂₀ alkyne, an arylene, or combinations thereof; each optionally substituted by one or more alkyl, alkenyl, hydroxyl, or halogen atoms.

Each of B₁ and B₂ is independently absent or a divalent form of imine, amine, carbonyl, ether, or ester, or combinations thereof.

Each of E₁ and E₂ is independently a (meth)acrylate, (meth)acrylamide, a C₁-C₂₀ alkyl, a C₃-C₂₀ cycloalkyl, a C₂-C₂₀ alkenyl, a C₂-C₂₀ alkynyl, an aryl, or combinations thereof, each optionally substituted by one or more alkyl, alkenyl, hydroxyl, or halogen atoms.

The term “divalent form” refers to a divalent radical that is formed when a hydrogen atom is removed from a functional group, e.g., a radical of alkyl, alkenyl, cycloalkyl, or alkynyl, etc., or when terminal hydrogen atoms are removed from a hydrocarbon, e.g., an alkane, alkene, cycloalkane, or alkyne, etc. For instance, in the case of divalent form of alkene (alkenylene), the term refers to a divalent radical that has hydrogen atoms removed from each of the two terminal carbon atoms of the alkene chain. A divalent form of a moiety is defined to represent the moiety present in the middle of a structural formula, with each end of the moiety bonding to another moiety, bond, or hydrogen atom.

In some embodiments, the crosslinker molecule is represented by Formula (I). In Formula (I), at least one of R¹, R², and R³ comprises a C═C double bond and at least one of R⁴, R⁵, and R⁶ comprise a C═C double bond. R¹, R², R³, R⁴, R⁵, and R⁶ may be the same or different. (R¹R²R³) and (R⁴R⁵R⁶) may be the same or different. In some embodiments, each of R¹ and R⁴ is H; each of R² and R⁵ may be H or alkyl, and each of R³ and R⁶ comprises a C═C double bond. In some embodiments, each of R³ and R⁶ independently comprises an alkene, an alkyne, a nitrile, an acyl, an acrylate, a (meth)acrylate, an acrylamine, a (meth)acrylamine, a styrene, or a vinyl pyridine.

In some embodiments, the crosslinker molecule is represented by Formula (II). In Formula (II), each of R⁷ and R¹ comprises a C═C double bond. X and Y may be the same or different. R⁷ and R⁸ may be the same or different. R⁷—CH(X)— and —CH(Y)—R⁸ may be the same or different. In some embodiments, each of X and Y independent represents CHR⁹R¹⁰, OH, SH, or NHR¹¹, wherein each of R⁹, R¹⁰, and R¹¹ is independently H or alkyl. In some embodiments, each of X and Y independent represents CHR⁹R¹⁰ or NHR¹¹, wherein each of R⁹, R¹⁰, and R¹¹ is independently H or methyl. In some embodiments, each of R⁷ and R⁸ independently comprises an alkene, an alkyne, a nitrile, an acyl, an acrylate, a (meth)acrylate, an acrylamine, a (meth)acrylamine, a styrene, or a vinyl pyridine.

In some embodiments, the crosslinker molecule is represented by Formula (III). In Formula (III), each of R⁷ and R⁸ comprises a C═C double bond. A₁ and A₂ may be the same or different. B₁ and B₂ may be the same or different. R⁷ and R⁸ may be the same or different. R⁷—B₁-A₁- and -A₂-B₂-R⁸ may be the same or different. In some embodiments, each of A₁ and A₂ is independently absent, a C₁-C₅ alkylene, a C₂-C₆ cycloalkylene, or a phenylene; each optionally substituted by one or more alkyl, hydroxyl, or halogen atoms. In some embodiments, each of B₁ and B₂ is independently absent or a divalent form of amine, amide, or ester. In some embodiments, each of R⁷ and R¹ is independently a C₂-C₂₀ alkenyl, optionally substituted by one or more C₁-C₃ alkyl. In some embodiments, each of R⁷ and R⁸ is independently an unsubstituted C₂-C₆ alkenyl. In some embodiments, each of R⁷ and R⁸ is independently comprises a C₂-C₂₀ alkynyl optionally substituted by one or more C₁-C₃ alkyl or a nitrile. Preferably, in Formula (III), n is 2 or 3 (e.g., n is 2), each of R⁷ and R⁸ is a C₂₋₂₀ alkenyl, optionally substituted by one or more alkyl or alkenyl; each of A₁ and A₂ is independently absent, a C₁-C₂₀ alkylene or a divalent form of phenyl; each optionally substituted by one or more alkyl, alkenyl, hydroxyl, or halogen atoms; and each of B₁ and B₂ is independently absent or a divalent form of amine, amide, ether, or ester.

In some embodiments, the crosslinker molecule is represented by Formula (IV). In Formula (IV), each of R¹⁵ and R¹⁶ comprises a C═C double bond. R¹⁵ and R¹⁶ may be the same or different.

In some embodiments, the crosslinker molecule is represented by Formula (V). In Formula (V), each of R¹⁷, R¹⁸, R¹⁹, and R²⁰ comprises a C═C double bond. R¹⁷, R¹⁸, R¹⁹, and R²⁰ may be the same or different.

In some embodiments, the crosslinker molecule is represented by Formula (VI). In Formula (VI), each of R¹⁷, R¹⁸, R¹⁹, and R²⁰ comprises a C═C double bond. R¹⁷, R¹⁸, R¹⁹, and R²⁰ may be the same or different. Each of E₁ and E₂ is independently a (meth)acrylate, (meth)acrylamide, a C₁-C₂₀ alkyl, a C₃-C₂₀ cycloalkyl, a C₂-C₂₀ alkenyl, a C₂-C₂₀ alkynyl, an aryl, or combinations thereof, each optionally substituted by one or more alkyl, alkenyl, hydroxyl, or halogen atoms.

In some embodiments, the crosslinker molecule has the structure of formula:

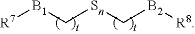

The integer n is 2 or 3. In one embodiment, n is 2. In another embodiment, n is 3. The integer t is 1 to 5, for instance 1 to 4, or 1 to 3. In one embodiment, t is 1. In one embodiment, t is 2. In one embodiment, t is 3. Each of R⁷ and R⁸ is independently a C₂-C₆ alkenyl, optionally substituted by one or more C₁-C₃ alkyl. In some embodiments, each of R⁷ and R⁸ is independently an unsubstituted C₂-C₆ alkenyl. In some embodiments, each of R⁷ and R⁸ is independently a C₂-C₄ alkenyl, substituted by one or more methyl. Each of B₁ and B₂ is independently absent, —O—, —OC(O)—, —C(O)O—, —C(O)—, —N(H)—, —N(H)C(O)—, or —C(O)N(H)—. In some embodiments, each of B₁ and B₂ is independently absent, —OC(O)—, —C(O)O—, —N(H)C(O)—, or —C(O)N(H)—.

In some embodiments, the crosslinker molecule has the structure of formula:

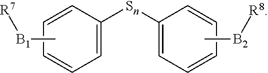

The integer n is 2 or 3. In one embodiment, n is 2. In one embodiment, n is 3. Each of R⁷ and R⁸ is independently a C₂-C₆ alkenyl, optionally substituted by one or more C₁-C₃ alkyl. In some embodiments, each of R⁷ and R⁸ is independently a unsubstituted C₂-C₆ alkenyl. In some embodiments, each of R⁷ and R⁸ is independently a C₂-C₄ alkenyl, substituted by one or more methyl. Each of B₁ and B₂ is independently absent, —O—, —OC(O)—, —C(O)O—, —C(O)—, —N(H)—, —N(H)C(O)—, or —C(O)N(H)—. In some embodiments, each of B₁ and B₂ is independently —OC(O)—, —C(O)O—, —N(H)C(O)—, or —C(O)N(H)—.

Exemplary crosslinker molecules are:

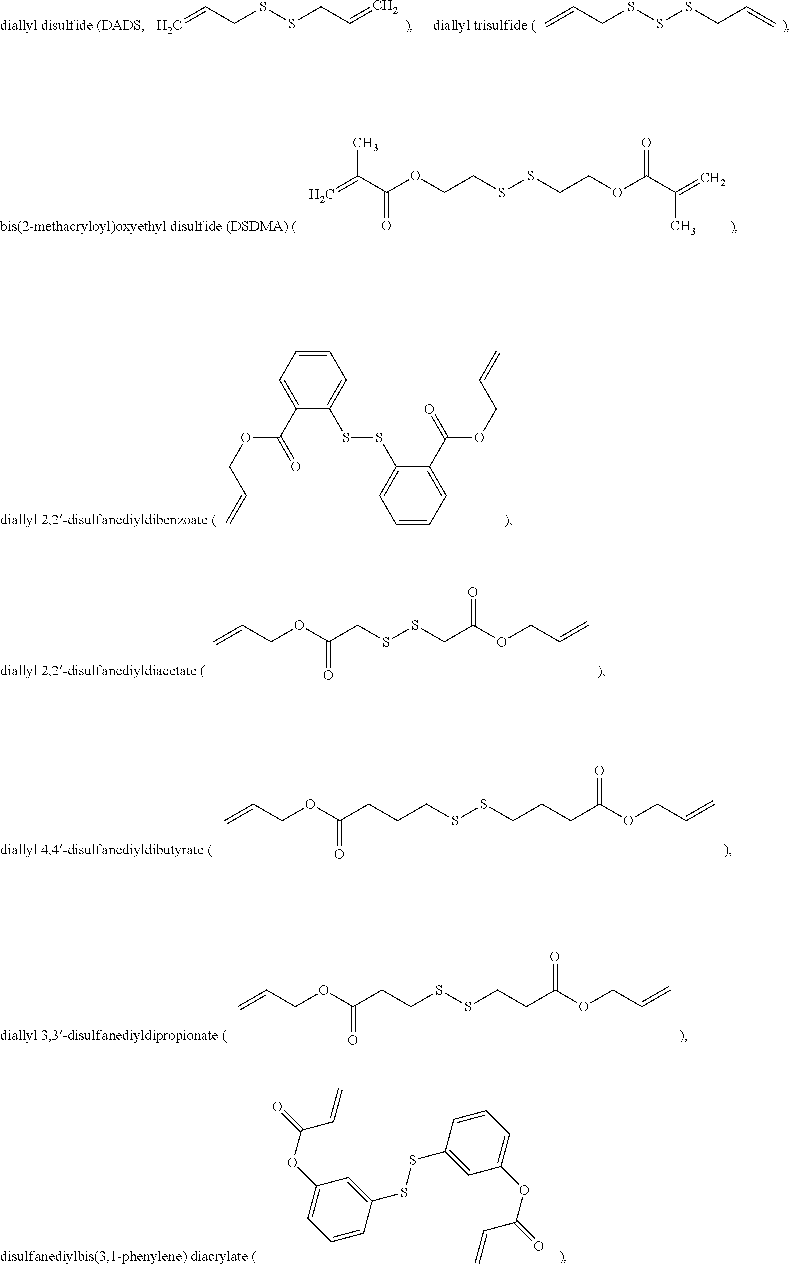

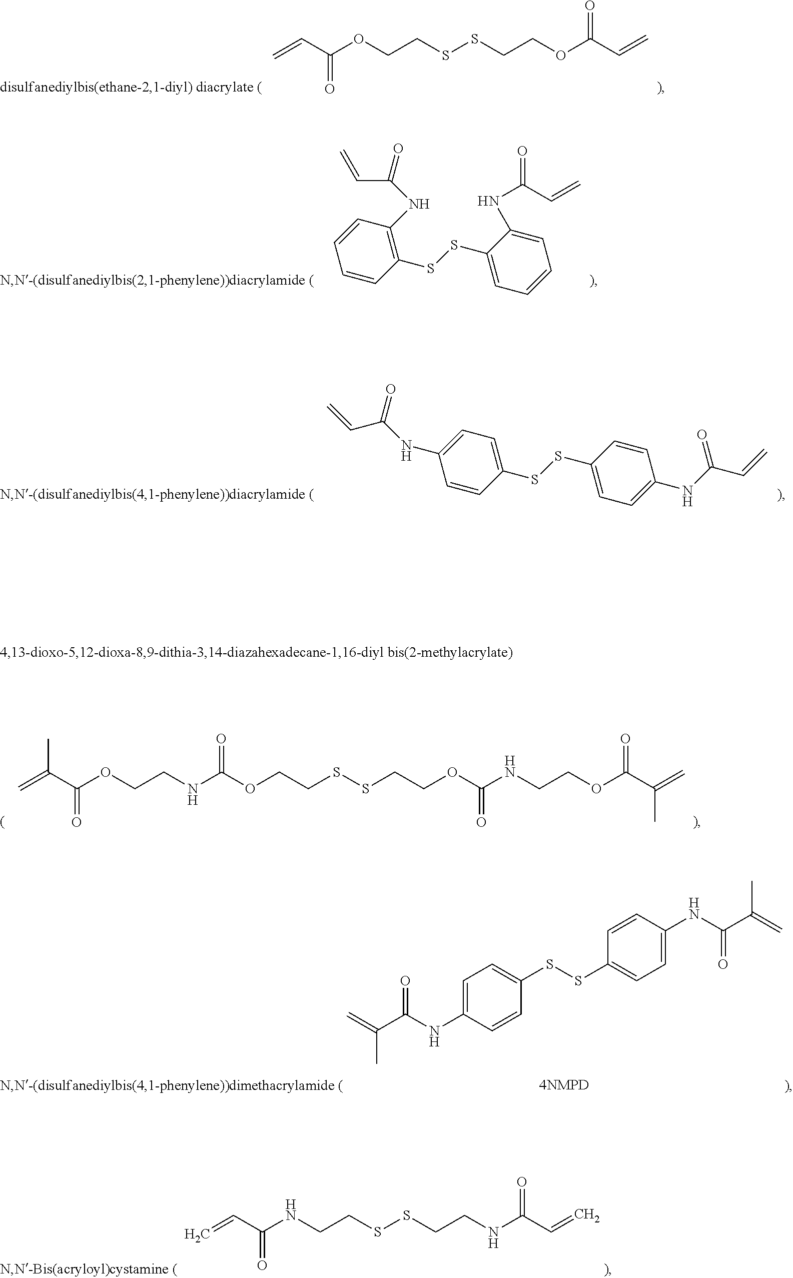

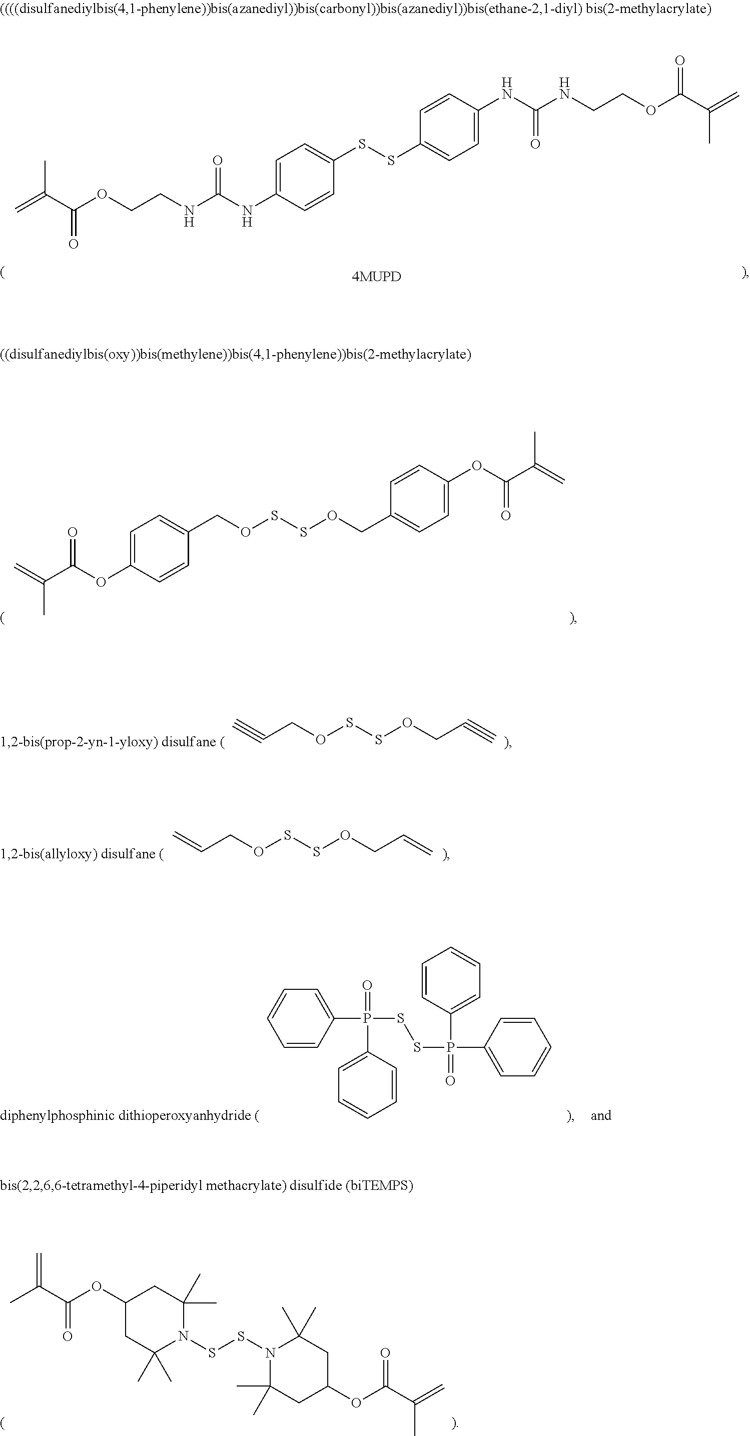

In some embodiments, the crosslinker molecule comprises diallyl disulfide, bis(2-methacryloyl)oxyethyl disulfide (DSDMA), and/or ((((disulfanediylbis(4,1-phenylene))bis(azanediyl))bis(carbonyl))bis(azanediyl))bis(ethane-2,1-diyl) bis(2-methylacrylate) (4MUPD). In one embodiment, the crosslinker consists of diallyl disulfide, bis(2-methacryloyl)oxyethyl disulfide (DSDMA), and/or ((((disulfanediylbis(4,1-phenylene))bis(azanediyl))bis(carbonyl))bis(azanediyl))bis(ethane-2,1-diyl) bis(2-methylacrylate) (4MUPD).

According to another embodiment, the crosslinker composition (i) comprises a disulfide crosslinker molecule wherein n is 2, and the purity of the disulfide crosslinker molecule in the crosslinker composition (i) is 90% or higher (e.g., 91% or higher, 92% or higher, 93% or higher, 94% or higher, 95% or higher, 96% or higher, 97% or higher, 98% or higher, 99% or higher, or about 100%).

Moreover, the crosslinker composition (i) comprises no more than 10% (such as no more than 9%, no more than 8%, no more than 7%, no more than 6%, no more than 5%, no more than 4%, no more than 3%, no more than 2%, no more than 1%, or about 0%) of a polysulfide crosslinker molecule wherein n is 3-8 (such as n is 3, 4, 5, 6, 7, or 8).

The one or more monomers in the reversibly-crosslinked polymer network can comprise an olefin monomer, a diene monomer, an acrylate monomer, a vinyl monomer, and combinations thereof.

Suitable olefin monomer can include a linear or branched olefin (e.g., an α-olefin) having 2 to 12 carbon atoms, 2 to 10 carbon atoms, or 2 to 8 carbon atoms. Exemplary linear or branched olefins includes, but are not limited to, ethylene, propylene, 1-butene, 2-butene, 1-pentene, 3-methyl-1-butene, 4-methyl-1-pentene, 3-methyl-1-pentene, 1-hexene, 3,5,5-trimethyl-1-hexene, 4,6-dimethyl-1-heptene, 1-heptene, 1-octene, 1-nonene, 1-decene, 1-undecene, and 1-dodecene. These olefins may contain one or more heteroatoms such as an oxygen, nitrogen, or silicon.

Suitable vinyl monomers can include a substituted vinyl, e.g., vinyl formate, vinyl acetate, or a vinyl ester having the formula of

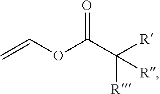

wherein R′, R″, and R′″ are independently H, branched or unbranched alkyl, or aryl (e.g., R′, R″, and R′″ can have a combined carbon number in the range of C₁ to C₂₀). Styrenic monomer is also one of the possibilities of monomers that can be used.

Suitable vinyl ester monomers include aliphatic vinyl esters having 3 to 20 carbon atoms (e.g., 4 to 10 carbon atoms, or 4 to 7 carbon atoms). Exemplary vinyl esters are vinyl acetate, vinyl formate, vinyl propionate, vinyl valerate, vinyl butyrate, vinyl isobutyrate, vinyl pivalate, vinyl caprate, vinyl laurate, vinyl stearate, and vinyl versatate. Aromatic vinyl esters such as vinyl benzonate can also be used as vinyl ester monomers. Common vinyl ester monomers are vinyl acetate, vinyl propionate, vinyl laurate, or vinyl versatate (e.g., the vinyl ester of versatic acid, vinyl neononanoate, or vinyl neodecanoate). Typically, vinyl acetate is used from the perspective of good commercial availability and impurity-treating efficiency at the production. The vinyl esters of neononanoic acid (vinyl neononanoate) and neodecanoic acid (vinyl neodecanoate) are commercial products obtained from the reaction of acetylene with neononanoic acids and neodecanoic acids, respectively, which are commercially available as Versatic acid 9 and Versatic acid 10.

The monomer may be used alone, or two or more different monomers may be used in combination, when being used in the polymerizable composition for making a reversibly-crosslinked polymer network.

In some embodiments, the one or more monomers in the reversibly-crosslinked polymer network comprise at least one member selected from the group consisting of ethylene, propylene, 1-butene, 1-pentene, 1-hexene, 1-heptene, 1-octene, and vinyl acetate.

In one embodiment, the monomer in the reversibly-crosslinked polymer network is ethylene and/or a vinyl ester. In another embodiment, the monomer in the reversibly-crosslinked polymer network is a mixture of ethylene and one or more vinyl esters.

In some embodiments, component (ii) comprises a polymer that may include a vinyl ester containing copolymer comprising ethylene, one or more branched vinyl ester monomers and optionally, vinyl acetate. According to an embodiment, the polymer is polyethylene, ethylene-vinyl ester copolymer, or a terpolymer of an ethylene-vinyl ester 1-vinyl ester 2, wherein vinyl ester 1 and vinyl ester 2 are two different vinyl esters. More preferably, the polymer is polyethylene, ethylene-vinyl ester copolymer, or an ethylene-vinyl acetate-vinyl versatate terpolymer (e.g., vinyl versatate may be a mixture of isomers of vinyl esters of versatic acid).

Suitable polymer compositions may include a vinyl ester containing copolymer incorporating various ratios of ethylene and one or more branched vinyl esters. In one or more embodiments, a vinyl ester containing copolymer may be prepared by reacting ethylene and a one or more branched vinyl ester in the presence of additional comonomers and one or more radical initiators to form a copolymer. In other embodiments, the polymer compositions may include a vinyl ester containing copolymer that is a terpolymer. The terpolymer may be prepared by reacting ethylene with a first comonomer to form a polymer resin or prepolymer, and then reacted with a second comonomer to prepare the final polymer composition, wherein the first and the second comonomer can be added in the same reactor or in different reactors. In one or more embodiments, the first comonomer may be one of more branched vinyl ester and the second comonomer may be vinyl acetate.

In one or more embodiments, vinyl ester containing copolymers may include a percent by weight of ethylene, based on the total weight of the vinyl ester containing polymers and measured by proton nuclear magnetic resonance (XH NMR) and Carbon 13 nuclear magnetic resonance (13C NMR), that ranges from a lower limit selected from one of 10 wt %, 20 wt %, or 30 wt %, to an upper limit selected from one of 60 wt %, 70 wt %, 80 wt %, 90 wt %, 95 wt %, 99.9 wt %, and 99.99 wt % where any lower limit may be paired with any upper limit.

According to an embodiment, the polymer comprises repeating units derived from an olefin monomer, a diene monomer, an acrylate monomer, a vinyl monomer, or combinations thereof. The polymer may have a molecular weight ranging from 1×10² g/mol to 1×10⁷ g/mol, measured according to gel permeation chromatography.

The free radical generator is a free-radical initiator, a thermal initiator, a radiation or irradiation initiator, or any combination thereof, and may comprise a peroxide (e.g., a bifunctional peroxide, a peracetate compound, etc.), an azo compound, a nitroxide, other —C—C— free radical initiators, and a mixture thereof.

Suitable peroxide compounds used as the initiator include, but are not limited to, a cyclic ketone peroxide, a bifunctional peroxide, a dialkyl peroxide, a monoperoxycarbonate, a poly (t-butyl) peroxycarbonates polyether, a di-peroxyketal, a perester (e.g., a peracetate), and mixtures thereof. In some embodiments, the peroxide compound is a cyclic ketone peroxide, a bifunctional peroxide, a dialkyl peroxide, or a mixture thereof.

Exemplary peroxide compounds used as the polymerization initiator are benzoyl peroxide; dicumyl peroxide; di-tert-butyl peroxide; tert-butyl cumyl peroxide; t-butyl-peroxy-2-ethyl-hexanoate; tert-butyl peroxypivalate; tertiary butyl peroxyneodecanoate; t-butyl-peroxy-benzoate; t-butyl-peroxy-2-ethyl hexanoate; tert-butyl 3,5,5-trimethylhexanoate peroxide; tert-butyl peroxybenzoate; 2-ethylhexyl carbonate tert-butyl peroxide; 2,5-dimethyl-2,5-di(tert-butylperoxide)hexane; 1,1-di(tert-butylperoxide)-3,3,5-trimethylcyclohexane; 2,5 dimethyl-2,5-di(tert-butylperoxide)hexyne-3; 3,3,5,7,7 pentamethyl-1,2,4-trioxepane; butyl 4,4-di(tert-butylperoxide) valerate; di(2,4-dichlorobenzoyl)peroxide; di(4-methylbenzoyl)peroxide; peroxide di(tert butylperoxyisopropyl)benzene; 2,5-di(cumylperoxy)-2,5-dimethyl hexane; 2,5-di(cumylperoxy)-2,5-dimethylhexyne; 3,4-methyl-4-(t-butylperoxy)-2-pentanol; 4-methyl-4-(t-amylperoxy)-2-pentanol; 4 methyl-4-(cumylperoxy)-2-pentanol; 4-methyl-4-(t-butylperoxy)-2-pentanone; 4-methyl-4-(t-amylperoxy)-2 pentanone; 4-methyl-4-(cumylperoxy)-2-pentanone; 2,5 dimethyl-2,5-di-t-butylperoxy)hexane; 2,5-dimethyl-2,5-di(t-amylperoxy)hexane; 2,5-dimethyl-2,5-di(t-butylperoxy)hexyne-3,2,5-dimethyl-2,5-di(t-amylperoxy)hexyne-3,2,5-dimethyl-2-t-butylperoxy-5-hydroperoxyhexane; 2,5-dimethyl-2-cumylperoxy-5-hydroperoxy hexane; 2,5-dimethyl-2-t-amylperoxy-5-hydroperoxyhexane; m/p-alpha, alpha-di[(t-butylperoxy)isopropyl]benzene; 1,3,5-tris(t-butylperoxyisopropyl)benzene; 1,3,5-tris(t-amylperoxyisopropyl)benzene; 1,3,5-tris(cumylperoxyisopropyl)benzene; di[1,3-dimethyl-3-(t-butylperoxy)butyl]carbonate; di[1,3-dimethyl-3-(t-amylperoxy)butyl]carbonate; di[1,3-dimethyl-3-(cumylperoxy)butyl]carbonate; di-t-amyl peroxide; t-amyl cumyl peroxide; t-butyl-isopropenylcumtyl peroxide; 2,4,6-tri(butylperoxy)-s-triazine; 1,3,5-tri[1-(t-butylperoxy)-1-methylethyl]benzene; 1,3,5-tri-[(t-butylperoxy)-isopropylbenzene; 1,3-dimethyl-3-(t-butylperoxy)butanol; 1,3-dimethyl-3-(t-amylperoxy)butanol; di(2-phenoxyethyl)peroxydicarbonate; di(4-t-butylcyclohexyl)peroxydicarbonate; dimyristyl peroxydicarbonate; dibenzyl peroxy decarbonate; di(isobornyl)peroxydicarbonate; 3-cumylperoxy-1,3-dimethylbutyl methacrylate; 3-t-butylperoxy-1,3-dimethylbutyl methacrylate; 3-t-amylperoxy-1,3-dimethylbutyl methacrylate; tri(1,3-dimethyl-3-t-butylperoxy butyloxy)vinyl silane; 1,3-dimethyl-3-(t-butylperoxy)butyl N-[1-{3-(1-methylethenyl)-phenyl)1-methylethyl]carbamate; 1,3-dimethyl-3-(t-amylperoxy)butyl N-[1-{3(1-methylethenyl)-phenyl}-1-methylethyl]carbamate; 1,3-dimethyl-3-(cumylperoxy))butyl N-[1-{3-(1-methylethenyl)-phenyl}-1-methylethyl]carbamate; 1,1-di(t-butylperoxy)-3,3,5-trimethylcyclohexane; 1,1-di(t-butylperoxy)cyclohexane; n-butyl 4,4-di(t-amylperoxy)valerate; ethyl 3,3-di(t-butylperoxy)butyrate; 2,2-di(t-amylperoxy)propane; 3,6,6,9,9-pentamethyl-3-ethoxycarbonylmethyl-1,2,4,5-tetraoxacyclononane; n-butyl-4,4-bis(t-butylperoxy)valerate; ethyl-3,3-di(t-amylperoxy)butyrate; benzoyl peroxide; OO-t-butyl-O-hydrogen-monoperoxy-succinate; OO-t-amyl-O-hydrogen-monoperoxy-succinate; 3,6,9, triethyl-3,6,9-trimethyl-1,4,7-triperoxynonane (or methyl ethyl ketone peroxide cyclic trimer); methyl ethyl ketone peroxide cyclic dimer; 3,3,6,6,9,9-hexamethyl-1,2,4,5-tetraoxacyclononane; 2,5-dimethyl-2,5-di(benzoylperoxy)hexane; t-butyl perbenzoate, t-butylperoxy acetate: t-butylperoxy-2-ethyl hexanoate; t-amyl perbenzoate; t-amyl peroxy acetate; t-butyl peroxy isobutyrate; 3-hydroxy-1,1-dimethyl-t-butyl peroxy-2-ethyl hexanoate; OO-t-amyl-O-hydrogen-monoepoxy succinate; OO-t-butyl-O-hydrogen-monoperoxy succinate; di-t-butyl diperoxyphthalate; t-butylperoxy (3,3,5-trimethylhexanoate); 1,4-bis(t-butylperoxycarbo)cyclohexane: t-butylperoxy-3,5,5-trimethylhexanoate; t-butyl-peroxy-(cis-3-carboxy)propionate; allyl 3-methyl-3-t-butylperoxy butyrate; OO-t-butyl-O-isopropylaminopropyl carbonate; OO-t-butyl-O-(2-ethyl hexyl) monoperoxy carbonate; 1,1,1-tris[2-(t-butylperoxy-carbonyloxy)ethoxymethyl]propane; 1,1,1-tris[2-(t-amylperoxy-carbonyloxy)ethoxymethyl]propane; 1,1,-tris[2-(cumylperoxy-carbonyloxy)ethoxymethyl]propane; OO-t-amyl-O-isopropylaminopropyl carbonate; di(4-methylbenzoyl)peroxide; di(3-methylbenzoyl)peroxide; di(2-methylbenzoyl)peroxide; didecanoyl peroxide; dilauroyl peroxide: 2,4-dibromo-benzoyl peroxide, succinic acid peroxide, dibenzoyl peroxide: di(2,4-dichloro-benzoyl)peroxide; di(2-ethylhexyl)peroxydicarbonate (EIPC), tert-amyl peroxypivalate (TAPPI); tert-butylperoxy-2-ethylhexanoate (TBPEH); tert-butylperoxyacetate (TBPA); and combinations thereof.

Suitable azo compounds used as the polymerization initiator include, but are not limited to azobisisobutyronitrile (AIBN); 2,2′-azobis(amidinopropyl) dihydrochloride; and azo-peroxide initiators that contain mixtures of a peroxide with one or more azodinitrile compounds including, e.g., 2,2′-azobis (2-methyl-pentanenitrile); 2,2′-azobis (2-methyl-butanenitrile); 2,2′-azobis (2-ethyl-pentanenitrile); 2-[(1-cyano-1-methylpropyl)azo]-2-methyl-pentanenitrile; 2-[(1-cyano-1-ethylpropyl)azo]-2-methyl-butanenitrile; and 2-[(1-cyano-1-methylpropyl)azo]-2-ethyl-pentanenitrile.

Accordingly, one embodiment of this application relates to a polymer network formed using a polymerization initiator that comprises at least one member selected from the group consisting of azobisisobutyronitrile (AIBN); 2,2′-azobis(amidinopropyl) dihydrochloride; and azo-peroxide initiators that contain mixtures of a peroxide with one or more azodinitrile compounds selected from the group consisting of 2,2′-azobis (2-methyl-pentanenitrile); 2,2′-azobis (2-methyl-butanenitrile); 2,2′-azobis (2-ethyl-pentanenitrile); 2-[(1-cyano-1-methylpropyl)azo]-2-methyl-pentanenitrile; 2-[(1-cyano-1-ethylpropyl)azo]-2-methyl-butanenitrile; and 2-[(1-cyano-1-methylpropyl)azo]-2-ethyl-pentanenitrile. Another embodiment of this invention relates to a polymer network having an initiator that comprises (a) at least one member selected from the group consisting of a peroxide, an azo compound, a peracetate compound, a nitroxide, azobisisobutyronitrile (AIBN); 2,2′-azobis(amidinopropyl) dihydrochloride; or (b) an azo-peroxide initiator that comprises a mixture of a peroxide with one or more azodinitrile compounds selected from the group consisting of 2,2′-azobis (2-methyl-pentanenitrile); 2,2′-azobis (2-methyl-butanenitrile); 2,2′-azobis (2-ethyl-pentanenitrile); 2-[(1-cyano-1-methylpropyl)azo]-2-methyl-pentanenitrile; 2-[(1-cyano-1-ethylpropyl)azo]-2-methyl-butanenitrile; and 2-[(1-cyano-1-methylpropyl)azo]-2-ethyl-pentanenitrile.

In some embodiments, the initiator comprises at least one member selected from the group consisting of 2,3-dimethyl-2,3-diphenylbutane; 3,4-dimethyl-3,4-diphenylhexane; 3,4-diethyl-3,4-diphenylhexane; 3,4-dibenzyl-3,4-ditolylhexane; 2,7-dimethyl-4,5-diethyl-4,5-diphenyloctane; and 3,4-dibenzyl-3,4-diphenylhexane.

According to some embodiments, the triggerable encapsulant material further comprises at least one additive selected from antioxidants, UV absorbers, light stabilizers, silane (adhesive properties) and peroxides.

### Triggerable Encapsulant Material Formation

Another aspect of the invention relates to a method of producing a triggerable encapsulant material, comprising reacting, by free radical reaction or polymerization, (i) a crosslinker composition comprising a crosslinker molecule having a —Sₙ— moiety and at least two polymerizable groups, wherein n is an integer of from 2 to 8, and (ii) a monomer, polymer, or combination thereof, comprising at least one C═C double bond or otherwise being capable of undergoing a free radical reaction or polymerization, in the presence of (iii) a free radical generator, to produce a triggerable encapsulant material comprising a reversibly-crosslinked polymer network containing polymer chains crosslinked via —S—S— bonds, which dissociate at a temperature of greater than 50° C. (e.g., greater than 75° C., greater than 100° C., greater than 125° C., or greater than 150° C.).

All above descriptions and all embodiments regarding the triggerable encapsulant material, including the crosslinkers, one or more monomers, and initiators, discussed above in the aspect are applicable to this aspect of the invention.

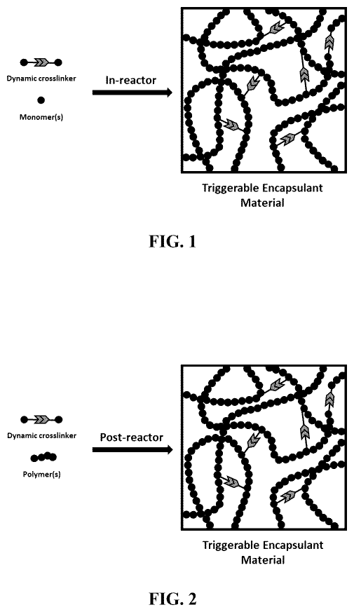

According to an embodiment, depicted by FIG. 1, the method of producing a triggerable encapsulant material comprises reacting, by polymerization, (i) a crosslinker composition comprising a crosslinker molecule having a —Sₙ— moiety and at least two polymerizable groups, wherein n is an integer of from 2 to 8, and (ii) a monomer comprising at least one C═C double bond or otherwise being capable of undergoing a free radical reaction or polymerization, in the presence of (iii) a free radical generator, to produce a triggerable encapsulant material comprising a reversibly-crosslinked polymer network containing polymer chains crosslinked via —S—S— bonds, which dissociate at a temperature of greater than 50° C. (e.g., greater than 100° C.).

During the reacting step, the one or more monomers form a polymer network via the at least one C═C double bond that allows the monomers to undergo a polymerization reaction. The crosslinker molecule has at least two polymerizable groups (e.g., a C═C double bond) that allow for the incorporation of the crosslinker molecule into the polymer network during polymerization reaction. Because of the polymerizable groups contained in the crosslinker molecule, the dynamic crosslinker can serve as another monomer during the polymerization, forming a copolymer or terpolymer with the monomer or monomers. For instance, polymerization of an ethylene monomer using diallyl disulfide, DSDMA or 4MUPD as the crosslinker molecule can generate an ethylene/(diallyl disulfide, DSDMA or 4MUPD) copolymer; polymerization of ethylene monomer and vinyl acetate monomer using a diallyl disulfide as the crosslinker can generate an ethylene/vinyl acetate/diallyl disulfide terpolymer. The crosslinker molecule also serve to link the polymer chains formed by the one or more monomers, forming an extensive crosslinking network.

The reaction reacting step may be carried out by free-radical initiation, thermal initiation, radiation or irradiation initiation, or combinations thereof.

The polymerization reaction can be carried out by various polymerization mechanisms known to one skilled in the art. For instance, free-radical polymerization is common polymerization mechanism and is suitable for the reaction herein. Free-radical polymerization is a type of chain-growth (chain-addition) polymerization that starts by initiating free radicals which add monomer units, thereby growing the polymer chain. Any type of initiation to generate free radicals (free radical initiation) can be used for the polymerization reactions. For instance, free radicals can be initiated by thermal initiation, radiation initiation (such as photo initiation), irradiation initiation (such as ionizing radiations, e.g., gamma and X-rays), or combinations thereof.

The reaction is typically carried out under a pressure above atmospheric pressure. For instance, the pressure for the polymerization and/or crosslinking reaction is at least 5 bar, and typically ranges from 5 bar to 5,000 bar, from 5 bar to 500 bar, from 5 bar to 200 bar, from 1000 bar to 5000 bar, from 1500 bar to 5000 bar, from 1000 bar to 3000 bar, from 1500 bar to 3000 bar, from 1000 bar to 2000 bar, or from 1000 bar to 3000 bar.

The reaction is typically carried out at an elevated temperature under a wide temperature range. The reaction temperature for the polymerization and/or crosslinking reaction is typically at least 30° C. (for instance, at least 50° C., at least 75° C., at least 100° C., at least 125° C., or at least 150° C.), and can range from 30° C. to 350° C. (for instance, from 150° C. to 350° C., from 150° C. to 280° C., from 150° C. to 230° C., from 150° C. to 180° C., from 30° C. to 280° C., from 30° C. to 230° C., from 30° C. to 180° C., from 30° C. to 130° C., from 50° C. to 350° C., from 50° C. to 150° C., or from 50° C. to 125° C.). Suitable reaction temperatures should take into consideration the polymerization initiator used and the dynamic crosslinker used. For instance, suitable reaction temperatures should be at least higher than the decomposition temperature of the polymerization initiator. Suitable reaction temperatures should also be no higher than the dissociation temperature of the crosslinker so that the crosslinking bonds (i.e., the disulfide or polysulfide linkages) in the crosslinker do not dissociate during the reaction.

The reaction conditions may also involve the use of an inert gas (e.g., N₂ gas).

The reaction may be carried out in the presence or absence of a solvent. The solvent may be used to dissolve the monomer or dynamic crosslinker. Suitable solvents include, but are not limited to, deep eutectic solvents; eutectic mixtures; ionic liquids; dimethyl carbonate (green solvent); ethers such as petroleum ether, tetrahydrofuran, or 1,4-dioxane; hydrocarbon solvents such as cyclohexane, heptane, or toluene; esters such as ethyl acetate; ketones (such as acetone or butanone or clyclohexanone); chlorinated solvents, such as dichloromethane; alcohols such as methanol, ethanol, butan-2-ol, butan-1-ol, isopropanol, ethylene glycol, or glycerol; and combinations thereof. In some embodiments, the solvent is water, DMSO, dimethylformamide, butyrolactone, or 1,4-dioxane. In some embodiments, the solvent is an anhydrous liquid. In one embodiment, the solvent is dimethyl carbonate.

The polymerization and/or crosslinking reaction may be carried out in a batch process as a bulk reaction or in a continuous process as a continuous reaction, under the reaction temperature and pressure as discussed above.

To initiate the polymerization and/or crosslinking reaction, the amount of the free radical generator present in the polymerizable composition typically ranges from 1×10⁻⁷ wt % to 5.0 wt %, for instance, from 0.001 wt % to 5.0 wt %, from 0.05 wt % to 5.0 wt %, from 0.01 wt % to 5.0 wt %, from 0.05 wt % to 5.0 wt %, from 0.01 wt % to 4.0 wt %, from 0.05 wt % to 4.0 wt %, from 0.01 wt % to 3.0 wt %, from 0.05 wt % to 3.0 wt %, from 0.01 wt % to 2.0 wt %, from 0.05 wt % to 2.0 wt %, from 0.01 wt % to 1.0 wt %, from 0.05 wt % to 1.0 wt %, from 0.1 wt % to 1.0 wt %, or from 0.1 wt % to 0.5 wt %, relative to 100 wt % of the total amount of the reversibly-crosslinked polymer network (comprising the crosslinker molecule, monomers and/or polymer, and free radical generator).

Suitable monomers for the polymerization and/or crosslinking reaction are those described herein above. In some embodiments, the one or more monomers for the polymerization and/or crosslinking reaction comprise an olefin monomer, a diene monomer, an acrylate monomer, a vinyl monomer, and combinations thereof. In some embodiments, the one or more monomers for the polymerization and/or crosslinking reaction comprise at least one member selected from the group consisting of ethylene, propylene, 1-butylene, 1-pentene, 1-hexene, 1-heptene, 1-octene, and vinyl acetate.

In one embodiment, the monomer for the polymerization and/or crosslinking reaction is ethylene. The ethylene polymer by polymerization may form high-density polyethylene (HDPE), linear low-density polyethylene (LLDPE), low-density polyethylene (LDPE), or medium-density polyethylene (MDPE).

In one embodiment, ethylene and vinyl acetate are used as monomers for the polymerization and/or crosslinking reaction. The copolymer of ethylene and vinyl acetate by polymerization may form ethylene-vinyl acetate copolymer (EVA), also known as poly (ethylene-vinyl acetate) (PEVA), the type of which depends upon different vinyl acetate (VA) content: e.g., low-VA (approximately up to 4%) EVA, which has properties similar to a LDPE but has increased gloss, softness, and flexibility; medium-VA (approximately 4-30%) EVA, having properties of a thermoplastic elastomer material; and high-VA (greater than 33%) EVA, having properties similar to a rubber.

The crosslinker molecule may be present in the polymerizable composition at various amounts, for instance, in an amount ranging from 0.01 wt % to 50 wt %, from 0.05 wt % to 50 wt %, from 0.1 wt % to 50 wt %, from 0.5 wt % to 50 wt %, from 1 wt % to 50 wt %, from 5 wt % to 50 wt %, from 0.1 wt % to 40 wt %, from 0.5 wt % to 40 wt %, from 1 wt % to 40 wt %, from 5 wt % to 40 wt %, from 0.1 wt % to 30 wt %, from 0.5 wt % to 30 wt %, from 0.1 wt % to 20 wt %, from 0.5 wt % to 20 wt %, from 1 wt % to 20 wt %, from 5 wt % to 20 wt %, from 0.1 wt % to 10 wt %, from 0.5 wt % to 10 wt %, from 1 wt % to 10 wt %, or from 5 wt % to 10 wt %, relative to 100 wt % of the total amount of the reversibly-crosslinked polymer network (comprising the crosslinker molecule, monomers and/or polymer, and free radical generator). In terms of mol %, the crosslinker molecule may be present in the polymerizable composition in an amount of at least 0.01 mol %, at least 0.05 mol %, at least 0.1 mol %, at least 0.5 mol %, at least 1 mol %, at least 2 mol %, at least 3 mol %, at least 4 mol %, at least 5 mol %, or in a range of from 0.01 mol % to 35 mol % (e.g., from 0.05 mol % to 35 mol %, from 0.1 mol % to 35 mol %, from 0.5 mol % to 35 mol %, from 1 mol % to 35 mol %, from 5 mol % to 35 mol %, from 1 mol % to 30 mol %, from 5 mol % to 30 mol %, from 1 mol % to 25 mol %, from 5 mol % to 25 mol %, from 1 mol % to 20 mol %, from 5 mol % to 20 mol %, from 1 mol % to 15 mol %, from 5 mol % to 15 mol %, from 1 mol % to 10 mol %, or from 5 mol % to 10 mol %), relative to 100 mol % of the total amount of the reversibly-crosslinked polymer network (comprising the crosslinker molecule, monomers and/or polymer, and free radical generator).

According to another embodiment, depicted by FIG. 2, the method of producing a triggerable encapsulant material comprises reacting, by free radical reaction, (i) a crosslinker composition comprising a crosslinker molecule having a —Sₙ— moiety and at least two polymerizable groups, wherein n is an integer of from 2 to 8, and (ii) a polymer comprising at least one C═C double bond or otherwise being capable of undergoing a free radical reaction or polymerization, in the presence of (iii) a free radical generator, to produce a triggerable encapsulant material comprising a reversibly-crosslinked polymer network containing polymer chains crosslinked via —S—S— bonds, which dissociate at a temperature of greater than 50° C. (e.g., greater than 100° C.).

According to this embodiment, a reaction between a molten polymer and a crosslinker composition takes place by grafting (e.g., free radical grafting in a solvent, in a melt-state, or in a solid-state), reactive extrusion, or melt mixing; preferably by reactive extrusion.

As one skilled in the art can appreciate, a reactive extrusion process is a manufacturing method that combines the traditionally separated chemical processes (polymer synthesis and/or modification) and extrusion (melting, mixing, melt mixing, blending, structuring, devolatilization and/or shaping) carried out onto an extruder. In this case, the chemical process is the reaction between the polymer (such as polyethylene polymer, polyethylene copolymer, or EVA polymer—a terpolymer of an ethylene-vinyl ester 1-vinyl ester 2) and the crosslinker (such as disulfide crosslinker), which takes place in an extruder.

The reactive extrusion process can be a single-step process, or reactive extrusion can involve two or more steps, performed in a sequence. In the multi-step process, the reaction between the polymer and the crosslinker can be completed in a later or additional heating step. The heating step can therefore represent the last step in the multi-step process. In one embodiment, the reactive extrusion process involves a melt mixing step that takes place at or above the softening temperature of the polymer. It can take place using any of an intermeshing mixer, a dispersing mixer, a high sheer mixer, a kneader, a single screw extruder, and a twin screw extruder, and a conical extruder.

In embodiments of the method, the melt-processing is carried out in an extruder. The melt-processing can be carried out at a temperature of at least 25° C. (for instance, at least 50° C., at least 75° C., at least 100° C., at least 125° C., at least 150° C., or at least 200° C.), and can range from 25° C. to 700° C., from 25° C. to 500° C., from 25° C. to 200° C., from 50° C. to 200° C., or from 50° C. to 100° C.

In embodiments using an extruder, the molten polymer, free radical generators and other components, may be added to an extruder, either simultaneously or sequentially, into the main or secondary feeder in the form of powder, granules, or flakes, where, in the case of the molten polymer, the addition of a powder, granule, or other solid form, takes place in such a way to melt the solid form polymer, to form the molten polymer. In one or more embodiments, methods may involve a single extrusion or multiple extrusions.

In one or more embodiments, the method is performed in a continuous process, such as in an extrusion. In one or more embodiments, the method involves melting a polyethylene-based composition in an extruder, decreasing the viscosity of the polyethylene-based composition, and extruding the melt through a die. In accordance with one or more embodiments, the melting and viscosity-decreasing steps may be repeated.

In case an extruder is used, it may be selected from a single-, twin-, or multi-screw extruder; in particular embodiments, a twin-screw extruder is used.

In one or more embodiments, the process may involve multiple extrusions in series, each of which results in an incorporation of crosslinker molecules from the ensemble, into the molten polymer. The multiple extrusions may be sequential or not. The processes of one or more embodiments may include one extrusion or more, or two extrusions or more. In embodiments where multiple extrusions are performed, each extrusion may be performed under conditions that are the same as, or different from, one another. In one or more embodiments, the repeated melting and viscosity decreasing steps are performed in a continuous loop system. The “continuous loop system” mean a system wherein the polyethylene-based composition enters in an extrusion, is processed and returned to the same extruder.

Additionally, the method according to the present invention comprises extruding the triggerable encapsulant material into at least one of a film and a multilayer film. This step may be carried out by using commonly known extruding processes for forming films, such as compression molding or cast film production, with a textured roll to provide texture to the film.

According to an embodiment, the film has a thickness of from 0.2 to 1.0 mm (measured according ASTM F2251), more precisely from 0.4 to 0.6 mm. Moreover, the film has a gel content higher than 60% (measured according solvent swelling, DSC-ASTM D-2765), a tensile strength higher than 20 mPa (measured according ASTM D882, using Instron) -and light transmission (380-1100 nm) higher than 90% (measured using UV-vis spectrometer, according to ASTM D1003, ASTM D542).

### The Reversibly-Crosslinked Polymer Network and its Reprocessing

The method discussed above results in a triggerable encapsulant material for photovoltaics comprising a reversibly-crosslinked polymer network. As discussed above, the method generates a triggerable encapsulant material for photovoltaics comprising reversibly-crosslinkable polymer network, obtained by the methods as described above.

The resulting reversibly-crosslinked polymer network contains a —S—S— bond that is dynamic and can undergo dissociation and reassociation at different conditions (e.g., upon changing the temperature), allowing for the polymer network to be re-processed and recycled when the polymer is subjected to a stimulus.

The resulting reversibly-crosslinked polymer network may be reprocessed by heating from a temperature at which dissociation of the reversible crosslinking bonds (e.g., —S—S— bonds) is inactive or substantially inactive (e.g., at room temperature) to an elevated temperature at which the dissociation of the reversible crosslinking bonds (e.g., —S—S— bonds) is activated or significantly enhanced (e.g., at temperatures greater than 50° C., greater than 60° C., greater than 70° C., greater than 80° C., greater than 90° C., greater than 100° C., greater than 110° C., greater than 120° C., greater than 130° C., greater than 140° C., or greater than 150° C., depending on the individual crosslinker used). Thus, suitable reprocessing/recycling temperatures can be at least 50° C., at least 60° C., at least 70° C., at least 80° C., at least 90° C., at least 100° C., at least 110° C., at least 120° C., at least 130° C., at least 140° C., or at least 150° C., depending on the individual crosslinker used. In some embodiments, the reprocessing/recycling temperatures are in a range of 120° C. to 160° C. The polymer networks may be reshaped (e.g., remolded) at the reprocessing/recycling temperatures. Then the reprocessed/recycled polymer networks can be cooled down, e.g., back to room temperature. During cooling, the reversible linkage (e.g., —S—S— bond) reassociates, thereby reforming the polymer network. A single reprocessing/recycling cycle may be a single round of heating, reshaping, and cooling. The heating used to reprocess/recycle the reversibly-crosslinkable polymer network can be relatively short (e.g., 5 hours, 4 hours, 3 hours, 2 hours, 1 hour, 30 minutes, or less) and still provide the reprocessed polymer network with full recovery of crosslinking density (as compared to the initial polymer network prior to any reprocessing/recycling).

The reversibly-crosslinked polymer network, after a reprocessing/recycling cycle, maintains, or significantly maintains, the polymer properties (as compared to those of the original polymer prior to any reprocessing/recycling). Thus, the triggerable encapsulant material and the methods described herein allow for preparation of a fully reprocessable/recyclable polymer (as compared to conventional polymers prepared without using the dynamic crosslinkers described herein). The resulting encapsulant materials are dynamic and therefore not only recyclable, but economically recyclable. Consequently, the triggerable materials according to the present invention maintain the properties of traditional PV encapsulant materials, while also providing greater ease of recyclability.

### Photovoltaic Module

Another aspect of the present invention relates to a photovoltaic module comprising one or more layers of a film formed from the triggerable encapsulant material as disclosed above.

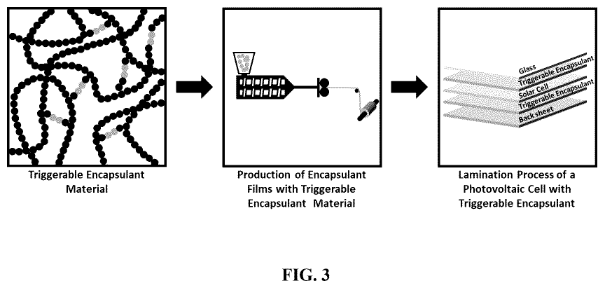

As depicted by FIG. 3, and as explained above, the triggerable encapsulant material is extruded into a film, and the film is subjected to a lamination process to form a photovoltaic cell, optionally followed by a curing step where the encapsulant material become crosslinked. In this regard, the photovoltaic cell comprises (a) a plurality of photovoltaic cells disposed on a bottom substrate, (b) a top substrate disposed on the plurality of photovoltaic cells, (c) one or more recyclable films formed from the triggerable encapsulant material, or combinations thereof.

According to an embodiment, the bottom and top substrates comprise polyethylene terephthalate (PET), or other fluoropolymers, such as polyvinyl fluoride (PVF), ethylene tetrafluoroethylene (ETFE), poly(vinylidene fluoride) (PVDF), and polytetrafluoroethylene (PTFE). According to another embodiment, the front sheet is made of glass.

Utilizing a triggerable encapsulant material in a PV module improve the decommissioning of a PV panel and recovery of other PV panel components.

### EXAMPLES

### Materials

Dicumyl peroxide (DCP) and polymer resins were used as received. 4,13-dioxo-5,12-dioxa-8,9-dithia-3,14-diazahexadecane-1,16-diyl bis(2-methylacrylate) (ADSA, crosslinker A) and 4,13-dioxo-5,12-dioxa-8,9-dithia-3,14-diazahexadecane-1,16-diyl bis(2-methylacrylate) (4MUPD, crosslinker B) was synthesized as described from procedures reported in literature.¹⁻³

### Example 1

An EVA copolymer (28 wt % vinyl acetate content) underwent reactive processing with various dynamic disulfide crosslinkers (motif: C-S-S-C) to produce a dynamically crosslinked EVA. The dynamically crosslinked polymer networks were prepared with a 25 mm co-rotating twin screw extruder. The base polymer resin (˜2200 g, MFR of 25 g/10 min), dynamic disulfide crosslinker, and a radical generator were dry blended together. The blend was added to the feeder of the extruder at 70° C. and reactive extrusion temperature at 160° C. See Table 1 for reactive extrusion parameters. The strands were pelletized to produce samples A1 and B1.

Samples A1 and B1 were then extruded on a COLLINS Lab & Pilot Solutions flat film line to produce a thin film. The film line includes a single screw extruder and two rollers. Pellets were fed into the feeder with no additional additives. See Table 2 for film extrusion parameters and samples A1-film and B1-film were produced with a 2 mm thickness.

Haze measurements were performed with a BYK hazemeter on film samples A1-film and B1-film using ASTM D1003. See Table 3 for haze measurements.

TABLE 1
Reactive extrusion parameters to produce dynamically
crosslinked EVA resins. Extrusions were performed
on a 25 mm twin-screw extruder.

| Sample | A1 | B1 |
|---|---|---|
| EVA amount (g) | 2208 | 2201 |
| Dynamic Disulfide | ADSA | 4MUPD |
| Dynamic Disulfide Amount | 1.6 | 1.9 |
| (wt %) | | |
| Radical Generator | DCP | DCP |
| Radical Generator Amount | 1 | 1 |
| (wt %) | | |
| Torque (%) | 19 | 23 |
| Screw speed (RPM) | 150 | 150 |
| Barrel Temperatures (° C.) | | |
| Zone 2 | 70 | 70 |
| Zone 3 | 100 | 100 |
| Zone 4 | 130 | 130 |
| Zone 5 | 160 | 160 |
| Zone 6 | 160 | 160 |
| Zone 7 | 160 | 160 |
| Zone 8 | 160 | 160 |
| Die Temperature (° C.) | 160 | 160 |
| Die Pressure (psi | 169 | 248 |
| Feed Rate (kg/hr) | 9 | 9 |

TABLE 2
Film extrusion parameters to produce triggerable
EVA films. Extrusions were performed on a COLLINS
Lab & Pilot Solutions flat film line.

| Sample | A1-film | B1-film |
|---|---|---|
| Melt Temperature (° C.) | 97 | 97 |
| Pressure (bar) | 139 | 139 |
| Screw Speed (RPM) | 70 | 70 |
| Amperage (%) | 2.3 | 2.3 |
| Extruder Barrel Temperatures (° C.) | | |
| Zone 1 | 50 | 50 |
| Zone 2 | 85 | 85 |
| Zone 3 | 100 | 100 |
| Zone 4 | 100 | 100 |
| Zone 5 | 100 | 100 |
| Zone 6 | 100 | 100 |
| Zone 7 | 100 | 100 |
| Die/Feedblock Temperatures (° C.) | | |
| Zone 1 | 100 | 100 |
| Zone 2 | 100 | 100 |
| Zone 3 | 100 | 100 |
| Zone 4 | 100 | 100 |
| Zone 5 | 100 | 100 |
| Chill Roll Speed (m/min) | 1 | 1 |
| Take Off Roll Speed (m/min) | 1 | 1 |
| Take Off Roll Torque (%) | 46 | 46 |
| Winder Speed (%) | 15 | 15 |
| Blower | ON | ON |

TABLE 3
Optical properties of film samples A1-film and B1-film.

| Sample | A1-film | B1-film |
|---|---|---|
| Haze (%) | 3.1 ± 0.1 | 19.1 ± 0.4 |

### Additional Embodiments

An embodiment of the invention relates to the triggerable encapsulant material herein, wherein the reversibly-crosslinked polymer network has at least one of:
a density ranging from 0.5 g/cm³ to 1.5 g/cm³, preferably from 0.8 g/cm³ to 1.3 g/cm³, measured according to ASTM D792; and
a melt index (12) ranging from 1 g/10 min to 100 g/10 min, measured according to ASTM D1238 (190° C. and load of 2.16 kg).

Another embodiment of the invention relates to the triggerable encapsulant material herein, wherein the reversibly-crosslinked polymer network, when in the form of a film, exhibits one or more of the following properties:
a melting temperature of less than 110° C., measured according to ASTM D3418;
   volumetric electrical resistivity greater than 1×1014 Ohm-cm, measured according to ASTM D257;
   a Shore A Hardness of less than 90, measured according to ASTM D2240;
   a Vicat Softening Point of less than 50° C., measured according to ASTM D1525;
   a contact angle greater than 80°, measured according to ASTM D5946;
   an optical transmittance of greater than 85%, measured according to ASTM D1003;
   a haze of less than 25%, measured according to ASTM D1003;
   a water vapor transmission coefficient of less than 22000 μm·g/m2·day, measured according to ASTM F1249;
   a stress at break of at least 5 MPa, measured according to ASTM D638;
   a strain at break of at least 500%, measured according to ASTM D638;
   a UV cut-off wavelength of 380 nm;
   an optical clarity of greater than 80%, measured according to ASTM D1003;
   glass transition temperature of less than −19° C. via tan 6 and lower than −29° C. via loss modulus, as measured via DMA, tensile fixture, tension°/min, according to ASTM D4065;
   a gloss at 450 of at least 77%, measured according to ASTM D2457; and/or
   a gloss at 600 of at least 90%, measured according to ASTM D2457.

Another embodiment of the invention relates to the triggerable encapsulant material herein, wherein the reversibly-crosslinked polymer network is in the form of a film, and the film exhibits one or more of the following properties:
a melting temperature of less than 110° C., measured according to ASTM D3418;
   volumetric electrical resistivity greater than 1×1014 Ohm·cm, measured according to ASTM D257;
   a Shore A Hardness of less than 90, measured according to ASTM D2240;
   a Vicat Softening Point of less than 50° C., measured according to ASTM D1525;
   a contact angle greater than 80°, measured according to ASTM D5946;
   an optical transmittance of greater than 85%, measured according to ASTM D1003;
   a haze of less than 25%, measured according to ASTM D1003;
   a water vapor transmission coefficient of less than 22000 μm·g/m²·day, measured according to ASTM F1249;
   a stress at break of at least 5 MPa, measured according to ASTM D638;
   a strain at break of at least 500%, measured according to ASTM D638;
   a UV cut-off wavelength of 380 nm;
   an optical clarity of greater than 80%, measured according to ASTM D1003;
   glass transition temperature of less than −19° C. via tan 6 and lower than −29° C. via loss modulus, as measured via DMA, tensile fixture, tension°/min, according to ASTM D4065;
   a gloss at 450 of at least 77%, measured according to ASTM D2457; and/or
   a gloss at 60° of at least 90%, measured according to ASTM D2457; and/or
a thickness in the range of 0.02 to 1.0 mm.

Another embodiment of the invention relates to the photovoltaic module herein, comprising a laminate that comprises the one or more layers of a film formed from the triggerable encapsulant material, wherein the laminate has at least one of:
a decrease in total light transmittance upon a damp heat test (65° C., 85% relative humidity and UV exposure) below 12%;
a decrease in total light transmittance upon a UV lamp ageing test (1000 W/m2, 65° C.) below 1%; and
a work of adhesion of at least 150 N·mm according to ASTMD3330.

1. A triggerable encapsulant material for photovoltaics, comprising:
a reversibly-crosslinked polymer network formed from the reaction product of:
(i) a crosslinker composition comprising a crosslinker molecule having a —Sₙ— moiety and at least two polymerizable groups, wherein n is an integer of from 2 to 8, and
(ii) a monomer, polymer, or combination thereof, comprising at least one C═C double bond or otherwise being capable of undergoing a free radical reaction or polymerization, in the presence of
(iii) a free radical generator,
wherein the reversibly-crosslinked polymer network contains polymer chains crosslinked via —S—S— bonds, which dissociate at a temperature of greater than 50° C.

2. The triggerable encapsulant material according to claim 1, wherein the crosslinker molecule in component (i) is represented by Formula (I), (II), (III), (IV), (V), or (VI): 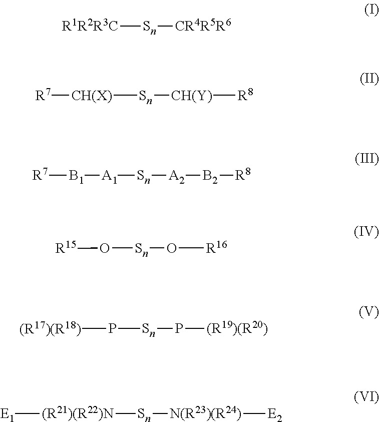
wherein:
n is an integer of from 2 to 8,
X represents CHR⁹R¹⁰, OH, SH, or NHR¹¹;
Y represents CHR¹²R¹³, OH, SH, or NHR¹⁴;
each of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, and R²⁴ is independently selected from the group consisting of a hydrogen atom, a halogen atom, a C₁₋₂₀ linear or branched alkyl, a C₂₋₂₀ alkenyl, a C₂₋₂₀ alkynyl, a nitrile, a hydroxyl, an ester having from 1 to 20 carbon atoms, an ether having from 1 to 20 carbon atoms, a thioether having from 1 to 20 carbon atoms, a ketone having from 1 to 20 carbon atoms, an imine, an amide, a primary amine, a secondary amine, a tertiary amine, a trifluoromethyl, a phenyl, a benzyl, a phenol, a pentafluorophenyl, a nitroxyl, and a silicone having from 1 to 20 carbon atoms; each optionally substituted by one or more alkyl, alkenyl, hydroxyl, or halogen atoms;
each of A₁ and A₂ is independently absent, a C₁-C₂₀ alkylene, a C₃-C₂₀ cycloalkylene, a divalent form of C₂-C₂₀ alkene, a divalent form of C₂-C₂₀ alkyne, an arylene, or combinations thereof, each optionally substituted by one or more alkyl, alkenyl, hydroxyl, or halogen atoms;
each of B₁ and B₂ is independently absent or a divalent form of imine, amine, amide, ether, or ester, or combinations thereof;
each of E₁ and E₂ is independently a (meth)acrylate, (meth)acrylamide, a C₁-C₂₀ alkyl, a C₃-C₂₀ cycloalkyl, a C₂-C₂₀ alkenyl, a C₂-C₂₀ alkynyl, an aryl, or combinations thereof, each optionally substituted by one or more alkyl, alkenyl, hydroxyl, or halogen atoms;
provided the following:
in Formula (I), at least one of R¹, R², and R³ comprises a C═C double bond and at least one of R⁴, R⁵, and R⁶ comprise a C═C double bond, and
in Formula (II) and (III), each of R⁷ and R⁸ comprises a C═C double bond,
in Formula (IV), each of R¹⁵ and R¹⁶ comprises a C═C double bond,
in Formula (V), at least one of R¹⁷ and R¹⁸ comprises a C═C double bond and at least one of R¹⁹ and R²⁰ comprise a C═C double bond, and
in Formula (VI), each of E₁ and E₂ comprises a C═C double bond.

3. The triggerable encapsulant material according to claim 1, wherein the C═C double bond is in a functional group comprising at least one member selected from the group consisting of an alkene, an alkyne, a nitrile, vinyl group, an acyl, an acrylate, a (meth)acrylate, acrylamide, a (meth)acrylamide, a styrene, a vinyl pyridine, or combinations thereof.

4. (canceled)

5. The triggerable encapsulant material according to claim 1, wherein the crosslinker composition (i) comprises at least one crosslinker molecule selected from the group consisting of:

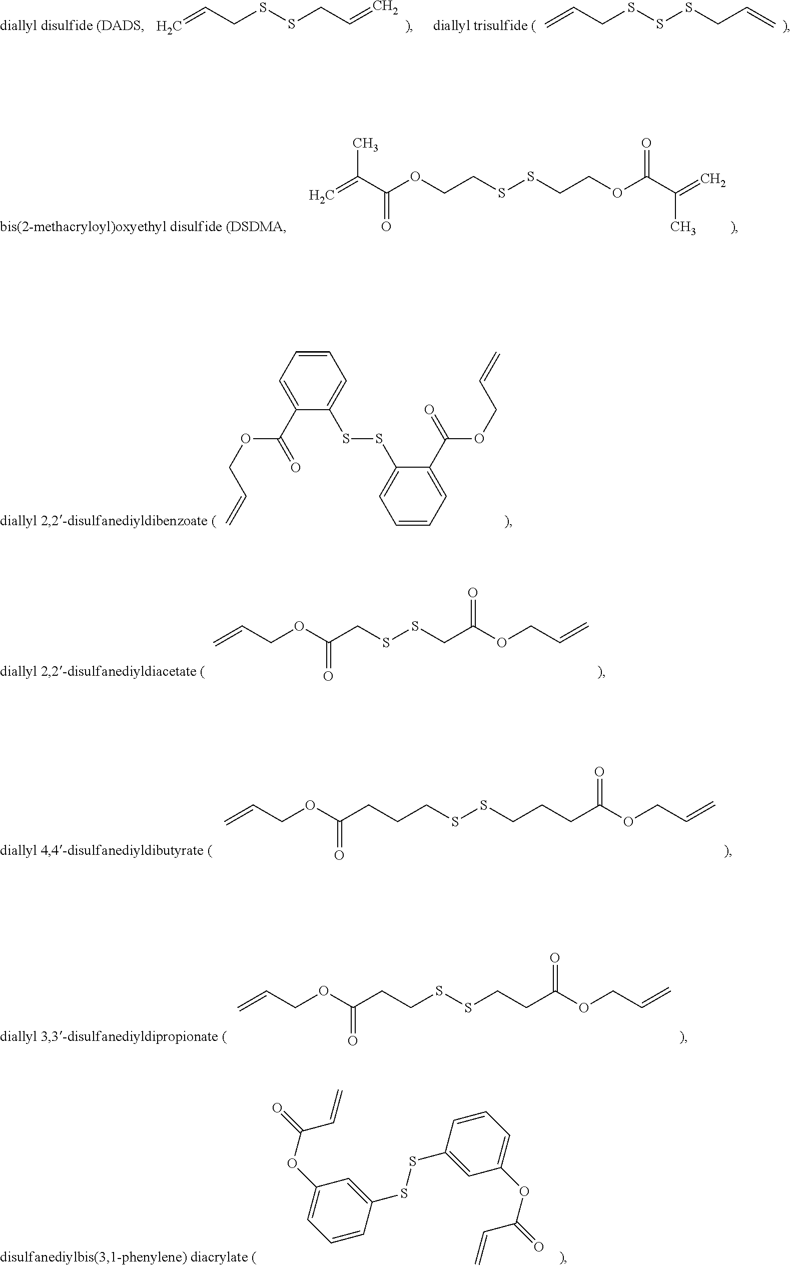

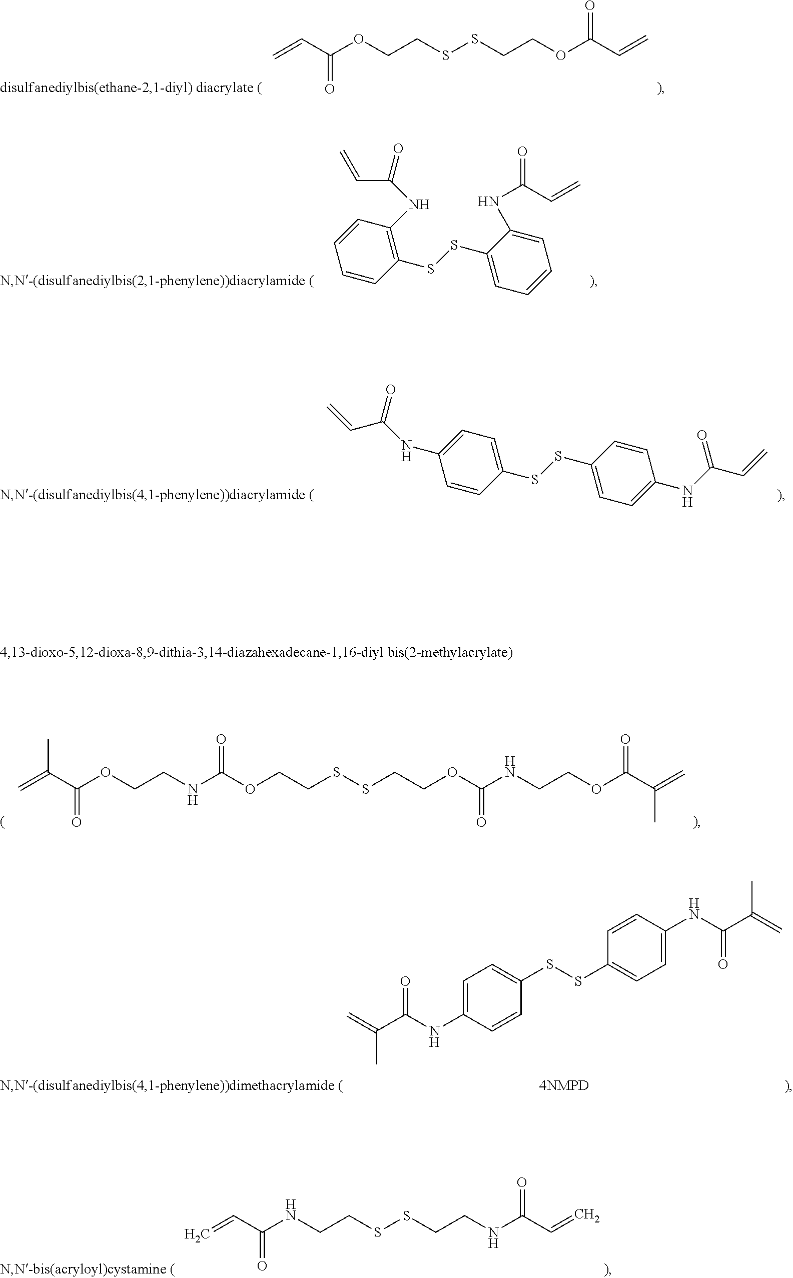

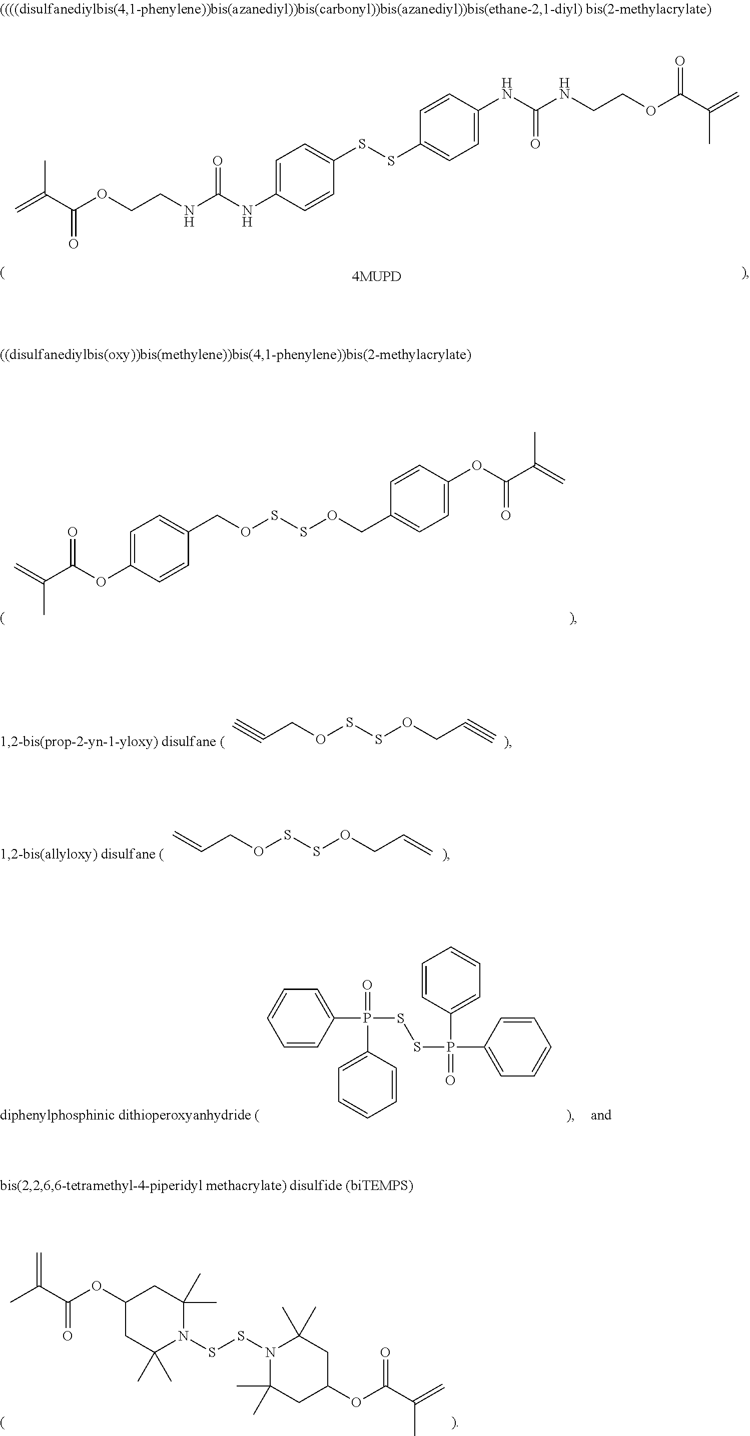

6. The triggerable encapsulant material according to claim 1, wherein the crosslinker composition (i) comprises a disulfide crosslinker molecule wherein n is 2, and
wherein the purity of the disulfide crosslinker molecule in the crosslinker composition (i) is 90% or higher.

7. The triggerable encapsulant material according to claim 6, wherein the disulfide crosslinker molecule is bis(2,2,6,6-tetramethyl-4-piperidyl methacrylate) disulfide comprising the two polymerizable groups.

8. The triggerable encapsulant material according to claim 1, wherein the crosslinker composition (i) comprises no more than 10%.

9. The triggerable encapsulant material according to claim 1, wherein component (ii) comprises a monomer selected from the group consisting of an olefin monomer, a diene monomer, an acrylate monomer, a vinyl monomer, and combinations thereof.

10. (canceled)

11. The triggerable encapsulant material according to claim 9, wherein the monomer is ethylene, one or more vinyl esters, or a mixture of ethylene and one or more vinyl esters.

12-13. (canceled)

14. The triggerable encapsulant material according to claim 1, wherein component (ii) comprises a polymer comprising repeating units derived from an olefin monomer, a diene monomer, an acrylate monomer, a vinyl monomer, or combinations thereof, wherein the polymer has a molecular weight of from 1×10² g/mol to 1×10⁷ g/mol, measured according to gel permeation chromatography.

15. The triggerable encapsulant material according to claim 14, wherein the polymer is polyethylene, ethylene-vinyl ester copolymer, or a terpolymer of an ethylene-vinyl ester 1-vinyl ester 2, wherein vinyl ester 1 and vinyl ester 2 are two different vinyl esters.

16. (canceled)

17. The triggerable encapsulant material according to claim 1, wherein the free radical generator is a free-radical initiator, a thermal initiator, a radiation or irradiation initiator, or any combination thereof.

18-19. (canceled)

20. A photovoltaic module comprising:
one or more layers of a film formed from the triggerable encapsulant material according to claim 1.

21. A method of producing a triggerable encapsulant material, comprising:
reacting, by free radical reaction or polymerization,
(i) a crosslinker composition comprising a crosslinker molecule having a —Sₙ— moiety and at least two polymerizable groups, wherein n is an integer of from 2 to 8, and
(ii) a monomer, polymer, or combination thereof, comprising at least one C═C double bond or otherwise being capable of undergoing a free radical reaction or polymerization, in the presence of
(iii) a free radical generator,
to produce a triggerable encapsulant material comprising a reversibly-crosslinked polymer network containing polymer chains crosslinked via —S—S— bonds, which dissociate at a temperature of greater than 50° C.

22-26. (canceled)

27. The method according to claim 21, wherein:
component (ii) comprises a polymer comprising repeating units derived from an olefin monomer, a diene monomer, an acrylate monomer, a vinyl monomer, or combinations thereof, wherein the polymer has a molecular weight of from 1×10² g/mol to 1×10⁷ g/mol, measured according to gel permeation chromatography; and
the reacting step is by grafting, reactive extrusion, or melt mixing.

28. (canceled)

29. The method according to claim 21, further comprising:
extruding the triggerable encapsulant material into at least one of a film and a multilayer film.

30. The method according to claim 21, further comprising:
reprocessing the reversibly-crosslinked polymer network at a temperature greater than room temperature to dissociate the crosslinking —S—S— bonds of the reversibly-crosslinked polymer.

31. The triggerable encapsulant material according to claim 1, wherein the reversibly-crosslinked polymer network has at least one of:
a density ranging from 0.5 g/cm³ to 1.5 g/cm³, measured according to ASTM D792; and
a melt index (I₂) ranging from 1 g/10 min to 100 g/10 min, measured according to ASTM D1238 (190° C. and load of 2.16 kg).

32. The triggerable encapsulant material according to claim 1, wherein the reversibly-crosslinked polymer network, when in the form of a film, exhibits one or more of the following properties:
a melting temperature of less than 110° C., measured according to ASTM D3418;
volumetric electrical resistivity greater than 1×10¹⁴ Ohm-cm, measured according to ASTM D257;
a Shore A Hardness of less than 90, measured according to ASTM D2240;
a Vicat Softening Point of less than 50° C., measured according to ASTM D1525;
a contact angle greater than 80°, measured according to ASTM D5946;
an optical transmittance of greater than 85%, measured according to ASTM D1003;
a haze of less than 25%, measured according to ASTM D1003;
a water vapor transmission coefficient of less than 22000 μm·g/m²·day, measured according to ASTM F1249;
a stress at break of at least 5 MPa, measured according to ASTM D638;
a strain at break of at least 500%, measured according to ASTM D638;
a UV cut-off wavelength of 380 nm;
an optical clarity of greater than 80%, measured according to ASTM D1003;
glass transition temperature of less than −19° C. via tan 6 and lower than −29° C. via loss modulus, as measured via DMA, tensile fixture, tension°/min, according to ASTM D4065;
a gloss at 45° of at least 77%, measured according to ASTM D2457;
a gloss at 60° of at least 90%, measured according to ASTM D2457; and/or
a thickness in the range of 0.02 to 1.0 mm.

33. (canceled)

34. The photovoltaic module according to claim 20, comprising a laminate that comprises the one or more layers of a film formed from the triggerable encapsulant material,
wherein the laminate has at least one of:
a decrease in total light transmittance upon a damp heat test (65° C., 85% relative humidity and UV exposure) below 12%;
a decrease in total light transmittance upon a UV lamp ageing test (1000 W/m², 65° C.) below 1%; and
a work of adhesion of at least 150 N·mm according to ASTMD3330.
